(19) United States
(12) Patent Application Publication
(10) Pub. No.: US 2013/0042901 A1
(43) Pub. Date: Feb. 21, 2013

(54) SOLAR TRACKING SYSTEM AND METHOD OF THE SAME

(71) Applicant: Yuan-Wei DENG, Taoyuan County (TW)

(72) Inventor: Yuan-Wei DENG, Taoyuan County (TW)

(73) Assignee: Du Pont Apollo Limited, Hong Kong (HK)

(21) Appl. No.: 13/213,103

(22) Filed: Aug. 19, 2011

(51) Int. Cl. H01L 31/052

(52) U.S. Cl. 136/246

(57) ABSTRACT

A solar tracking system and method are provided. The solar tracking system comprises a photovoltaic cell device, a light sensor module to detect intensity of sunlight, a driving device, a history database, a time generator for generating an accurate present time and a control module. The control module controls the driving device to change an attitude of the photovoltaic cell device to track the sun by referencing sun position data entries in the history database according to the accurate present time and determine whether the intensity of the sunlight exceeds a specific threshold. When the intensity of the sunlight exceeds a specific threshold, the sun is tracked according to the intensity of sunlight and a present sun position is recorded in the history database. On the contrary, a restricted area around a referenced sun position data entry is searched to track the sun.

### BACKGROUND

1. Technical Field

The present disclosure relates to a solar tracking mechanism. More particularly, the present disclosure relates to a solar tracking system and a method of the same.

2. Description of Related Art

In a conventional photovoltaic system, a photovoltaic device uses optical devices to concentrate a large area of sunlight, or solar thermal energy, onto photovoltaic cells. Concentrating solar thermal energy in this manner reduces the required area of the photovoltaic cells to thereby make the system cost-effective. However, this also makes the system sensitive to the incident angle of the sunlight. Accordingly, the precision of a tracking system becomes more and more important.

However, when the sun is blocked by clouds, fog or the shadows of other objects, the resulting diffused light makes it hard to determine the actual position of the sun. In this case, the maximum value of light intensity is detected by a light sensor module on the basis of diffused light, instead of on the basis of light received directly from the sun. Consequently, the precision of the tracking system degrades.

Some conventional sun tracking systems use a complex solar orbit function to calculate the position of the sun to adjust the attitude of the photovoltaic cell device. The calculation of the complex solar orbit function is reliable only when the initial position of the sun is precisely set. If the initial position of the sun is incorrectly set, the resulting calculation is in error. Therefore, a precise initial setting is necessary in such a conventional sun tracking system.

Accordingly, there is a need for a solar tracking system and a method of the same that are able to maintain high precision. The present disclosure addresses such a need.

### SUMMARY

An aspect of the present disclosure is to provide a solar tracking system. The solar tracking system comprises a photovoltaic cell device, a light sensor module, a driving device, a history database, a time generator and a control module. The photovoltaic cell device comprises a plurality of photovoltaic cells. The light sensor module detects an intensity of sunlight. The driving device changes an attitude of the photovoltaic cell device. The history database records a plurality of sun position data entries each corresponding to a specific time in the past. The time generator generates an accurate present time. The control module control the driving device to change the attitude of the photovoltaic cell device to track the sun by referencing the sun position data entries on the basis of the accurate present time and determines whether the intensity of the sunlight exceeds a specific threshold retrieved from the history database on the basis of the accurate present time. The control module tracks the sun according to the intensity of sunlight and records a present sun position as one of the sun position data entries in the history database. When the intensity of the sunlight is at or below the specific threshold, the control module searches a restricted area around a referenced sun position data entry to track the sun.

According to an embodiment of the present disclosure, when the intensity of the sunlight exceeds the specific threshold, the control module controls the driving device to modulate the attitude of the photovoltaic cell device such that the attitude of the photovoltaic cell device corresponds to a real-time maximum value of the intensity of the sunlight.

According to another embodiment of the present disclosure, the control module retrieves a part of the sun position data entries according to a certain range of time before and after the accurate present time to define the restricted area. The control module is further configured to control the driving device to modulate the attitude of the photovoltaic cell device to a position corresponding to an area maximum value of the intensity of the sunlight within the restricted area.

According to yet another embodiment of the present disclosure, the solar tracking system further comprises a tracking device associated with the photovoltaic cell device such that the driving device drives a motor of the tracking device to control the attitude of the photovoltaic cell device.

According to still another embodiment of the present disclosure, the solar tracking system further comprises an attitude sensor associated with the photovoltaic cell device such that the attitude sensor detects the attitude of the photovoltaic cell device and transmits attitude data of the photovoltaic cell device to the control module. The control module makes adjustments in the attitude of the photovoltaic cell device on the basis of the attitude data.

According to another embodiment of the present disclosure, the solar tracking system further comprises an uninterruptible power system, a display interface and a control input interface. The uninterruptible power system supplies power to the time generator. The display interface displays an operation condition and of the solar tracking system. The control input interface adjusts the operation parameter and modifies a tracking mode of the solar tracking system.

Another aspect of the present disclosure is to provide a solar tracking method for a solar tracking system. The solar tracking method comprises the steps as outlined in the sentences that follow. The intensity of the sunlight is detected. A driving device of the solar tracking system is controlled to change an attitude of a photovoltaic cell device of the solar tracking system to track the sun by referencing a plurality of sun position data entries on the basis of an accurate present time, wherein each of the sun position data entries corresponds to a specific time in the past and is recorded in a history database of the solar tracking system. It is determined whether the intensity of the sunlight exceeds a specific threshold retrieved from the history database on the basis of the accurate present time. When the intensity of the sunlight exceeds the specific threshold, a present sun position is recorded as one of the sun position data entries in the history database. When the intensity of the sunlight is at or below the specific threshold, a restricted area around a referenced sun position data entry is searched to track the sun.

According to an embodiment of the present disclosure, when the intensity of the sunlight exceeds the specific threshold, the driving device is controlled to change the attitude of the photovoltaic cell device such that the attitude of the photovoltaic cell device corresponds to a real-time maximum value of the intensity of the sunlight.

According to another embodiment of the present disclosure, when the intensity of the sunlight is at or below the specific threshold, the solar tracking method further comprises a step of retrieving a part of the sun position data entries according to a certain range of time before and after the accurate present time to define the restricted area. The solar tracking method further comprises a step of controlling the driving device to further modulate the attitude of the photovoltaic cell device to a position corresponding to an area maximum value of the intensity of the sunlight within the restricted area

According to yet another embodiment of the present disclosure, the solar tracking method further comprises a step of driving a motor of a tracking device associated with the photovoltaic cell device to control the attitude of the photovoltaic cell device.

According to still another embodiment of the present disclosure, the solar tracking method further comprises a step of supplying power to the time generator by an uninterruptible power system.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiments of the disclosure, with reference made to the accompanying drawings as follows:

FIG. 1 is a block diagram of a solar tracking system in an embodiment of the present disclosure;

FIG. 2 is a perspective view of a photovoltaic cell device and a driving device in an embodiment of the present disclosure; and

FIG. 3 is a flow chart of a solar tracking method in an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

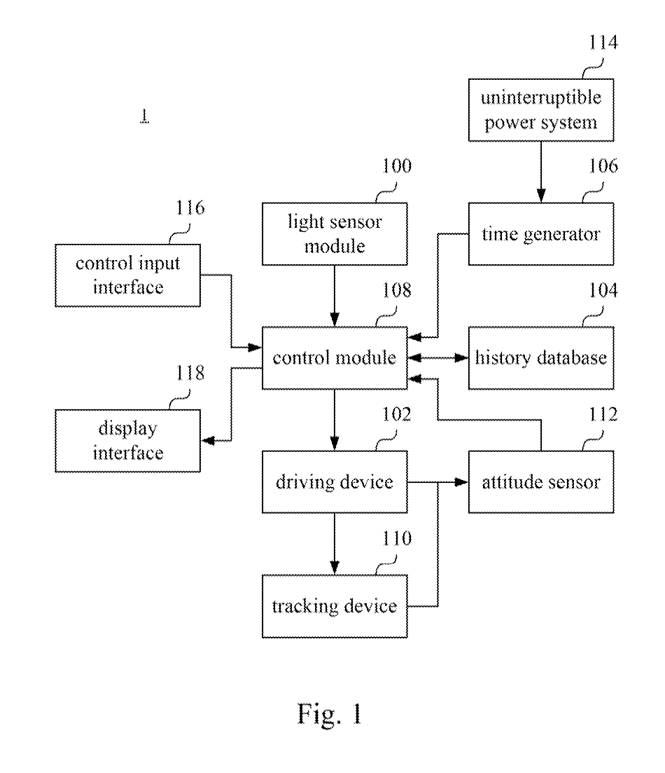

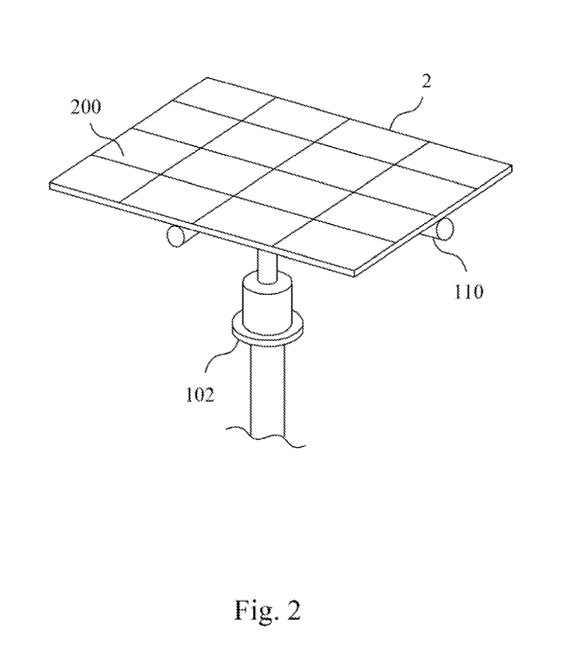

FIG. 1 is a block diagram of a solar tracking system 1 in an embodiment of the present disclosure. The solar tracking system 1 comprises a light sensor module 100, a driving device 102, a history database 104, a time generator 106, a control module 108 and a photovoltaic cell device 2 (see FIG. 2).

Referring also to FIG. 2, which is a perspective view of the photovoltaic cell device 2 and the driving device 102 in an embodiment of the present disclosure, the photovoltaic cell device 2 comprises a plurality of photovoltaic cells 200. The driving device 102 is able to change an attitude of the photovoltaic cell device 2. In an embodiment, the attitude includes an azimuth angle and an elevation angle of the photovoltaic cell device 2. By adjusting the azimuth angle and the elevation angle, the photovoltaic cell device 2 can be controlled to an appropriate orientation to absorb the energy of the sunlight and further convert it into electrical power. In the present embodiment, the solar tracking system 1 further comprises a tracking device 110 connected to or otherwise associated with the photovoltaic cell device 2 as shown in FIG. 2. The driving device 102 drives a motor of the tracking device 110 to control the attitude of the photovoltaic cell device 2.

The light sensor module 100 detects the intensity of the sunlight incident to the photovoltaic cell device 2. Meanwhile, the control module 108 controls the driving device 102 to drive the motor of the tracking device 110 to change the attitude of the photovoltaic cell device 2 to track the sun by referencing one of a plurality of sun position data entries recorded in the history database 104 on the basis of an accurate present time generated by the time generator 106. In certain embodiments, the driving device 102 may utilize a DC motor, pulse motor, servo motor, hydraulic system, or linear actuator.

In an embodiment, the solar tracking system 1 further comprises an attitude sensor 112 that can detect the attitude of the photovoltaic cell device 2 indirectly through the driving device 102 or the tracking device 110 and transmit attitude data of the photovoltaic cell device 2 to the control module 108. As a result, the control module 108 can determine what, if any, adjustments in the attitude of the photovoltaic cell device 2 are required.

The history database 104 records a plurality of sun position data entries each corresponding to a specific time in the past. For example, the coordinates of the sun may be recorded every minute of every hour of every day in a month every year. Hence, using time as an index, it is easy to determine the position of the sun corresponding to specific times in the history database 104. In an embodiment, the history database 104 can be stored in a memory in the control module 108 to thereby be a part of the control module 108.

The time generator 106 generates an accurate present time including the second, minute, hour, day, month and year of the present time. In an embodiment, the solar tracking system 1 further comprises an uninterruptible power system 114 to supply power to the time generator 106. Hence, the time generator 106 can generate the accurate present time with precision, even if the normal power system of the solar tracking system 1 fails.

The control module 108 further determines whether the intensity of the sunlight exceeds a specific threshold. In an embodiment, the specific threshold is the intensity of the sunlight corresponding to the sun position data entries that is referenced according to the accurate present time. In an embodiment, when the intensity of the sunlight exceeds the specific threshold, the control module 108 further determines that the sun is not blocked by any objects such as clouds, or fog or the shadows of other objects. Accordingly, the control module 108 controls the driving device 102 to modulate the attitude of the photovoltaic cell device 2 such that the attitude of the photovoltaic cell device 2 corresponds to the maximum value of the intensity of the sunlight. The photovoltaic cell device 2 can therefore receive the sunlight with the highest intensity.

On the other hand, when the intensity of the sunlight is at or below the specific threshold, the control module 108 further determines that the sun is blocked by objects such as clouds, fog or the shadows of other objects. When the sun is blocked, the diffused light makes it hard to determine the actual position of the sun. In this case, the maximum value of the light intensity is detected by the light sensor module 100 on the basis of the diffused light, instead of on the basis of light received directly from the sun.

Accordingly, when the intensity of the sunlight is at or below the specific threshold, the control module 108 retrieves a part of the sun position data entries according to a certain range of time before and after the accurate present time to define a restricted area at first. In other words, these positions of the sun form the said restricted area. In an embodiment, the range of time can be thirty seconds before and after the accurate present time, sixty seconds before and after the accurate present time or other possible range of time. Consequently, the control module 108 is further configured to control the driving device 102 to modulate the attitude of the photovoltaic cell device 2 to a position corresponding to an area maximum value of the intensity of the sunlight within the restricted area.

For example, if the sun is blocked by something (e.g. clouds, fog or the shadows of other objects) at 2:00 p.m., the intensity of the sunlight may decrease, such that the control module 108 determines that the intensity of the sunlight is at or below the specific threshold. The control module 108 therefore searches the history database 104 according to a certain range of time before and after the accurate present time provided by the time generator 106, i.e., 1:59 p.m. to 2:01 p.m. The history database 104 may record the position of the sun within the time interval 1:59 p.m. to 2:01 p.m. every day throughout a month. Hence, the control module 108 can access the recorded sun position data entries to define the restricted area. In an embodiment, the control module 108 obtains one of the reference positions on the basis of only one of the accessed entries or on the basis of an average of a plurality of the accessed entries. The control module 108 further searches the restricted area to find a position that has the highest intensity of the sunlight within the restricted area. The attitude of the photovoltaic cell device 2 is further modulated to that position corresponding to the maximum value of the intensity of the sunlight detected by the light sensor module 100 within the restricted area. The maximum value of the intensity of the sunlight within the restricted area may also be referred to as an “area maximum value” herein, and the maximum value of the intensity of the sunlight used when the specific threshold is exceeded may be referred to as a “real-time maximum value” herein.

Accordingly, the control module 108 can modulate the attitude of the photovoltaic cell device 2 according to the intensity of the sunlight directly when the intensity of the sunlight exceeds the specific threshold after referencing the sun position data entries on the basis of the accurate present time. Moreover, when the intensity of the sunlight is at or below the specific threshold, the control module 108 can further modulate the attitude of the photovoltaic cell device 2 within the restricted area. Hence, erroneous modulation of the attitude of the photovoltaic cell device 2 resulting from determining the maximum value of light intensity from diffused light rather than from light received directly from the sun may be avoided, thereby ensuring high operating efficiency of the photovoltaic cell device 2.

In an embodiment of the present disclosure, the solar tracking system 1 further comprises a control input interface 116 and a display interface 118. Through the display interface 118, the user can observe the operation condition and various parameters of the solar tracking system 1. The control input interface 116 is either a wired or a wireless control interface. The user can adjust the parameters related to the tracking mechanism described above through the control input interface 116. Furthermore, the user can modify a tracking mode of the solar tracking system through the control input interface 116. In other words, the user can determine whether the tracking mechanisms of the solar tracking system 1 described above is activated. In an embodiment, the solar tracking system 1 can be controlled to track the sun only on the basis of the detection result of the light sensor module. In another embodiment, the solar tracking system 1 can be controlled to track the sun only on the basis of the reference of the sun position data entries according to the accurate present time.

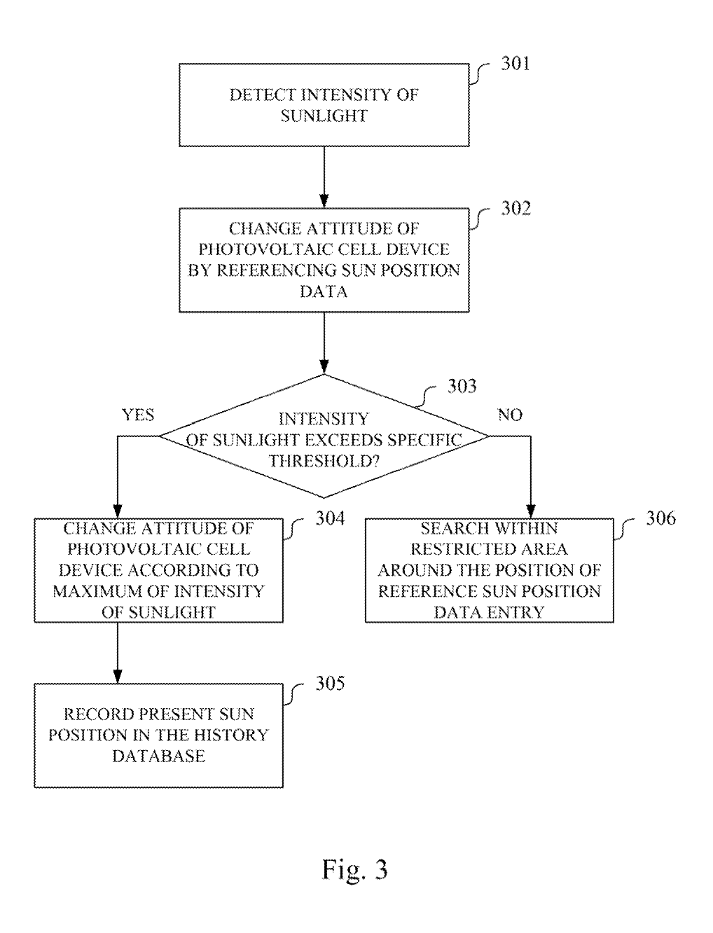

FIG. 3 is a flow chart of a solar tracking method in an embodiment of the present disclosure. The solar tracking method can be implemented by the solar tracking system 1 depicted in FIG. 1. The solar tracking method comprises the steps as outlined in the sentences that follow (The steps are not recited in the sequence in which the steps are performed. That is, unless the sequence of the steps is expressly indicated, the sequence of the steps is interchangeable, and all or part of the steps may be simultaneously, partially simultaneously, or sequentially performed).

In step 301, the intensity of the sunlight is detected by the light sensor module 100. In step 302, a driving device 102 of the solar tracking system 1 is controlled to change an attitude of a photovoltaic cell device 2 of the solar tracking system 1 to track the sun by referencing one of a plurality of sun position data entries on the basis of an accurate present time. In step 303, a determination is made by the control module 108 as to determine whether the intensity of the sunlight exceeds a specific threshold.

When the intensity of the sunlight exceeds the specific threshold, the attitude of the photovoltaic cell device 2 is changed according to a maximum value of the intensity of the sunlight in step 304. The present sun position is further recorded in the history database 104 in step 305.

When the intensity of the sunlight is at or below the specific threshold, a restricted area around a referenced sun position data entry is searched to track the sun in step 306.

Accordingly, the control module 108 can determine whether the intensity of the sunlight exceeds the specific threshold to determine how best to modulate the attitude of the photovoltaic cell device 2, such that high efficiency of the photovoltaic cell device 2 may be maintained.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A solar tracking system comprising:
a photovoltaic cell device comprising a plurality of photovoltaic cells;
a light sensor module to detect an intensity of sunlight;
a driving device to change an attitude of the photovoltaic cell device;
a history database to record a plurality of sun position data entries each corresponding to a specific time in the past;
a time generator to generate an accurate present time; and
a control module configured to control the driving device to change the attitude of the photovoltaic cell device to track the sun by referencing the sun position data entries on the basis of the accurate present time and determine whether the intensity of the sunlight exceeds a specific threshold retrieved from the history database on the basis of the accurate present time,
when the intensity of the sunlight exceeds the specific threshold, the control module tracks the sun according to the intensity of sunlight and records a present sun position as one of the sun position data entries in the history database;
when the intensity of the sunlight is at or below the specific threshold, the control module searches a restricted area around a referenced sun position data entry to track the sun.

2. The solar tracking system of claim 1, wherein when the intensity of the sunlight exceeds the specific threshold, the control module controls the driving device to modulate the attitude of the photovoltaic cell device such that the attitude of the photovoltaic cell device corresponds to a real-time maximum value of the intensity of the sunlight.

3. The solar tracking system of claim 1, wherein the control module retrieves a part of the sun position data entries according to a certain range of time before and after the accurate present time to define the restricted area.

4. The solar tracking system of claim 3, wherein the control module is further configured to control the driving device to modulate the attitude of the photovoltaic cell device to a position corresponding to an area maximum value of the intensity of the sunlight within the restricted area.

5. The solar tracking system of claim 1, further comprising a tracking device associated with the photovoltaic cell device such that the driving device drives a motor of the tracking device to control the attitude of the photovoltaic cell device.

6. The solar tracking system of claim 1, further comprising an attitude sensor associated with the photovoltaic cell device such that the attitude sensor detects the attitude of the photovoltaic cell device and transmits attitude data of the photovoltaic cell device to the control module, wherein the control module is further configured to make adjustments in the attitude of the photovoltaic cell device on the basis of the attitude data.

7. The solar tracking system of claim 1, further comprising an uninterruptible power system to supply power to the time generator.

8. The solar tracking system of claim 1, further comprising a display interface to display an operation condition and of the solar tracking system.

9. The solar tracking system of claim 8, further comprising a control input interface to adjust the operation parameter and modify a tracking mode of the solar tracking system.

10. A solar tracking method for a solar tracking system comprising the steps of:
detecting an intensity of sunlight;
controlling a driving device of the solar tracking system to change an attitude of a photovoltaic cell device of the solar tracking system to track the sun by referencing a plurality of sun position data entries on the basis of an accurate present time, wherein each of the sun position data entries corresponds to a specific time in the past and is recorded in a history database of the solar tracking system;
determining whether the intensity of the sunlight exceeds a specific threshold retrieved from the history database on the basis of the accurate present time;
when the intensity of the sunlight exceeds the specific threshold, recording a present sun position as one of the sun position data entries in the history database; and
when the intensity of the sunlight is at or below the specific threshold, searching a restricted area around a referenced sun position data entry to track the sun.

11. The solar tracking method of claim 10, wherein when the intensity of the sunlight exceeds the specific threshold, the driving device is controlled to change the attitude of the photovoltaic cell device such that the attitude of the photovoltaic cell device corresponds to a real-time maximum value of the intensity of the sunlight.

12. The solar tracking method of claim 10, wherein when the intensity of the sunlight is at or below the specific threshold, further comprising a step of retrieving a part of the sun position data entries according to a certain range of time before and after the accurate present time to define the restricted area.

13. The solar tracking method of claim 12, further comprising a step of controlling the driving device to further modulate the attitude of the photovoltaic cell device to a position corresponding to an area maximum value of the intensity of the sunlight within the restricted area.

14. The solar tracking method of claim 10, further comprising a step of driving a motor of a tracking device associated with the photovoltaic cell device to control the attitude of the photovoltaic cell device.

15. The solar tracking method of claim 10, further comprising a step of supplying power to the time generator by an uninterruptible power system.
